(19) United States
(12) Patent Application Publication
(10) Pub. No.: US 2020/0326228 A1
(43) Pub. Date: Oct. 15, 2020

(54) VIBRATION AND TEMPERATURE INTERGRATED SENSOR

(71) Applicant: FATRI (Xiamen) Technologies, Co., Ltd., Xiamen City (CN)

(72) Inventors: Yongzhong Nie, Xiamen City (CN); Chengxu Luo, Xiamen City (CN)

(21) Appl. No.: 16/575,595

(22) Filed: Sep. 19, 2019

(30) Foreign Application Priority Data
Apr. 15, 2019 (CN) 201920507808.7

(51) Int. Cl. G01H 11/08; H01L 41/113; H01L 41/187; G01M 13/028; G01K 7/24; G01D 11/24; G01K 1/08; B61C 9/32

(52) U.S. Cl. CPC G01H 11/08; H01L 41/1132; H01L 41/187; B61C 9/32; G01K 7/24; G01D 11/245; G01K 1/08; G01M 13/028

(57) ABSTRACT

The present application refers to the field of sensing device, in particular to a vibration and temperature integrated sensor, comprising a vibration sensor body; a temperature sensor body, coupled to the vibration sensor body; wherein, the vibration sensor body comprises a first casing and a vibration sensing assembly disposed inside the first casing; a shielding case is disposed outside the vibration sensing assembly; and the shielding case and the first casing have an insulating layer therebetween. The vibration and temperature integrated sensor of the present application has strong insulation and voltage resistance, strong working stability and enhanced working life.

### CROSS REFERENCE TO RELATED APPLICATIONS

This application claims priority to Chinese Patent Application No. 2019205078087, filed on Apr. 15, 2019, the entire contents of which are incorporated herein by reference.

### TECHNICAL FIELD

The present application refers to the field of sensing device, in particular to a vibration and temperature integrated sensor.

### BACKGROUND

A high-speed train gearbox is a key device for high-speed train power transmission. It is one of top ten supporting technologies for high-speed EMU and one of the most important transmission links in the EMU transmission system. The requirements for the accuracy and reliability of high-speed train gearbox are high, and whether the high-speed train gearbox is in a good state has a great effect on driving safety.

During the fault diagnosis of gearbox, there is a lot of information, such as the vibration signal that can quickly and directly reflect the operating state of the gearbox, used for detection and diagnosis. According to statistics, more than 70% of faults will be manifested in the form of vibration. At the same time, the temperature field of the gearbox constantly changes as the train speed increases and the operating environment changes constantly. The operation of the gearbox may be adversely affected by too high or too low temperature. In addition, the high-speed train is provided with numerous electrical equipments, which work in complex working environment, on. In order to avoid the high-voltage breakdown of apparatus used for the diagnosis of the gearbox, such apparatus usually is required to have insulation and high voltage resistance. However, in prior art, the integrated sensor capable of simultaneously measuring the vibration and temperature of the gearbox has poor voltage resistance and poor working stability, which may affects the working life.

### SUMMARY

Therefore, the technical problem to be solved by the present application is to overcome the technical defects in prior art that the integrated sensor capable of simultaneously measuring the vibration and temperature of the gearbox has poor voltage resistance and poor working stability, which may affect the working life, thereby providing a vibration and temperature integrated sensor with strong voltage resistance, strong working stability and enhanced working life.

In order to solve the above technical problem, the technical solutions adopted by the present application are as follows.

A vibration and temperature integrated sensor comprises a vibration sensor body; a temperature sensor body, coupled to the vibration sensor body; wherein, the vibration sensor body comprises a first casing and a vibration sensing assembly disposed inside the first casing; a shielding case is disposed outside the vibration sensing assembly; and the shielding case and the first casing have an insulating layer therebetween.

In the above vibration and temperature integrated sensor, the insulating layer comprises an insulating spacer, disposed at a bottom of the vibration sensing assembly, being in contact with the first casing, and connected to an opening of the shielding case to form a bearing chamber for bearing the vibration sensing assembly; a pouring sealant, filled between the shielding case and the first outer casing.

In the above vibration and temperature integrated sensor, the vibration sensing assembly comprises: a support, disposed on a side of the insulating spacer away from the first casing; a piezoelectric ceramic, disposed in a ring shape and sleeved on the columnar protrusion; a mass block, having a groove structure that fits the piezoelectric ceramic; a signal processing circuit board, spaced apart from a side of the mass block away from the insulating spacer, and connected to an inner wall of the shielding case and a signal transmission line extending from the shielding case; a columnar protrusion is disposed on one side of the support away from the insulating spacer; and the piezoelectric ceramic is disposed in the groove structure.

In the above vibration and temperature integrated sensor, the shielding case comprises a first layer structure for protecting the vibration sensing assembly and supporting the signal processing circuit board, and a second layer structure for shielding the first casing from interfering with the signal processing circuit board.

In the above vibration and temperature integrated sensor, the temperature sensor body is a probe structure.

In the above vibration and temperature integrated sensor, the temperature sensor body comprises a second casing connected to the first casing, and a thermal resistor, disposed in the second casing and connected to a signal transmission line extending to an interior of the first casing.

In the above vibration and temperature integrated sensor, the second casing is internally filled with the pouring sealant.

In the above vibration and temperature integrated sensor, further comprising a 12-core connector connected to the first casing, and a connector connected to the 12-core connector via a signal transmission cable; wherein, the signal transmission line connected to the signal processing circuit board and the signal transmission line connected to the thermal resistor are respectively connected to the 12-core connector.

In the above vibration and temperature integrated sensor, both of the 12-core connector and the connector are connected to the signal transmission cables by an adapter.

In the above vibration and temperature integrated sensor, a circuit, formed by a bidirectional transient voltage suppressing diode, a gas discharge tube, and an unidirectional diode, is disposed between the 12-core connector and the signal processing circuit board.

The technical solutions of the present application have the following advantages.

1. The vibration and temperature integrated sensor provided by the present application comprises a vibration sensor body; a temperature sensor body, coupled to the vibration sensor body; wherein, the vibration sensor body comprises a first casing and a vibration sensing assembly disposed inside the first casing; a shielding case is disposed outside the vibration sensing assembly; and the shielding case and the first casing have an insulating layer therebetween. The vibration sensor body and temperature sensor body are designed to simultaneously monitor the vibration state and temperature state of the gearbox; the shielding case and the insulating layer are designed to insulate the vibration sensing assembly from the first casing and achieve electromagnetic shielding to achieve effects of isolation and insulation, so as to meet the requirements of high voltage resistance and enable the vibration sensing assembly to have an excellent signal-to-noise ratio, which is good for capturing fine signals; the insulating layer is designed to enhance the working stability and working life of the vibration sensor body.

2. In the vibration and temperature integrated sensor provided by the present application, the insulating layer comprises an insulating spacer, disposed at a bottom of the vibration sensing assembly; being in contact with the first casing, and connected to an opening of the shielding case to form a bearing chamber for bearing the vibration sensing assembly; a pouring sealant, filled between the shielding case and the first outer casing. The pouring sealant is designed to achieve the effects of fixation and insulation, and guarantee the voltage resistance requirements of the vibration sensing assembly. The insulating spacer may insulate and isolate the vibration sensor assembly from the first casing base, and insulate the internal vibration sensing assembly and the shielding case from the first casing together with the pouring sealant. This structural design is effective in ensuring the sealing requirements and voltage resistance requirements of the vibration sensor body.

3. In the above vibration and temperature integrated sensor provided by the present application, the shielding case comprises a first layer structure for protecting the vibration sensing assembly and supporting the signal processing circuit board, and a second layer structure for shielding the first casing from interfering with the signal processing circuit board. The shielding case is designed into a double-layer structure to ensure that the vibration sensing assembly has excellent anti-interference ability and lightning protection.

4. In the above vibration and temperature integrated sensor provided by the present application, the temperature sensor body is a probe structure. The probe structure is designed to be separated from the vibration sensor body, so that the two sensor bodies meet their respective temperature ranges, which reduces the temperature resistance requirement of the vibration sensor body. The two sensors have good independence and strong anti-interference ability, which improves the signal acquisition accuracy.

5. In the above vibration and temperature integrated sensor provided by the present application, the second casing is internally filled with the pouring sealant, so as to reduce the temperature response time of the resistor, and play a role of fixation and insulation, which can effectively guarantee the sealing requirement and voltage resistance requirement of the temperature sensor body.

6. In the above vibration and temperature integrated sensor provided by the present application, a circuit, formed by a bidirectional transient voltage suppressing diode, a gas discharge tube, and an unidirectional diode, is disposed between the 12-core connector and the signal processing circuit board, so as to improve the environmental adaptability of the sensor, which enables the signal processing circuit board to work normally under the action of an electrical fast pulse group.

### BRIEF DESCRIPTION OF THE DRAWING

One or more embodiments are illustrated by way of example, and not by limitation, in the figures of the accompanying drawings, wherein elements having the same reference numeral designations represent like elements throughout. The drawings are not to scale, unless otherwise disclosed.

In order to more clearly illustrate the technical solutions of the embodiments of the present application or the prior art, the drawings used in the embodiments of the present application or the prior art will be briefly described below. Obviously, the drawings in the following description are only some embodiments of the present application, and those skilled in the art can obtain other drawings based on these drawings without any creative efforts.

FIG. 1 is a schematic structural view of a vibration and temperature integrated sensor of the present application;

FIG. 2 is a partial cross-sectional view of the vibration and temperature integrated sensor shown in FIG. 1;

FIG. 3 is a cross-sectional view of a temperature sensor body of the vibration and temperature integrated sensor shown in FIG. 1.

In the drawings, the reference numerals are:

1-first casing; 2-second casing; 3-12-core connector; 4-signal transmission cable; 5-adapter; 6-connector; 7-signal processing circuit board; 8-pouring sealant; 9-shielding case; 10-Mass block; 11-piezoelectric ceramic; 12-support; 13-gas discharge tube; 14-bidirectional transient voltage suppressing diode; 15-thermal resistor; 16-signal transmission line.

### DETAILED DESCRIPTION

The technical solutions of the present application will be described clearly and completely with reference to the accompanying drawings. It is obvious that the described embodiments are only a part of the embodiments of the present application, and not all of the embodiments. All other embodiments obtained by those skilled in the art based on the embodiments of the present application without any creative efforts are within the scope of the present application.

Further, the technical features involved in the different embodiments of the present application described below may be combined with each other as long as they do not constitute a conflict with each other.

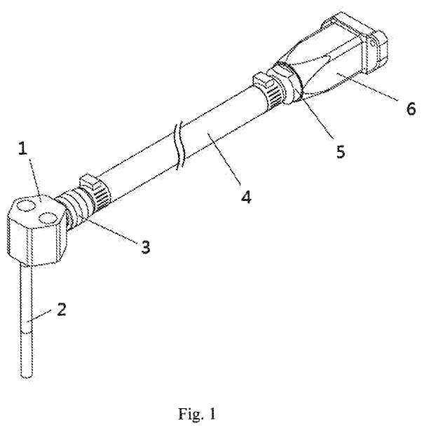

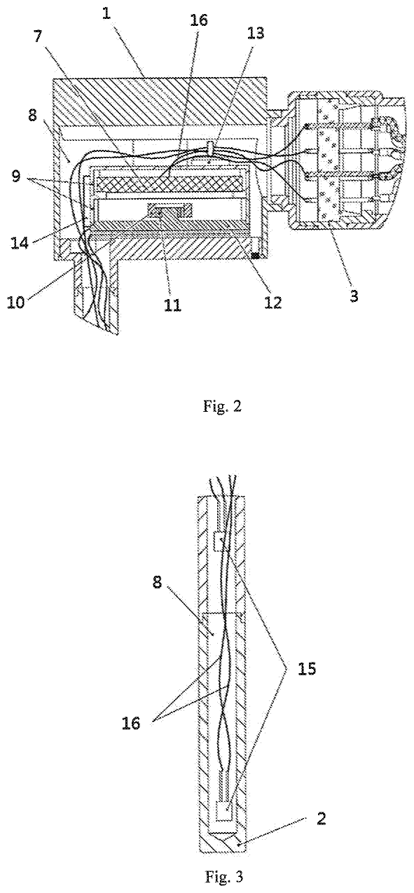

As shown in FIGS. 1-3, the embodiment provides a vibration and temperature integrated sensor for monitoring an operation of train gearbox. The vibration and temperature integrated sensor may simultaneously detect the vibration and temperature of the train gearbox, and includes a vibration sensor body, a temperature sensor body, a 12-core connector 3, a signal transmission cable 4, and a connector 6. In this embodiment, the vibration sensor body is mounted to the gearbox to be tested by bolts.

In this embodiment, the vibration sensor body comprises a first casing 1 and a vibration sensing assembly disposed inside the first casing 1. A shielding case 9 is disposed outside the vibration sensing assembly, which is composed of a piezoelectric acceleration sensor sub-assembly. The shielding case 9 and the first casing 1 have an insulating layer therebetween. The vibration sensor body has a rectangular structure to meet performance requirement of the vibration sensing assembly in the case where the first casing 1 has a small internal space.

Further, the insulating layer comprises an insulating spacer, disposed at a bottom of the vibration sensing assembly, being in contact with the first casing 1, and connected to an opening of the shielding case 9 to form a bearing chamber for bearing the vibration sensing assembly; a pouring sealant 8, filled between the shielding case 9 and the first outer casing 1. The pouring sealant 8 and the insulating spacer form the insulating layer for isolating the shielding case 9 from the vibration sensing assembly and the first casing 1 located inside the shielding case 9. In this embodiment, the insulating spacer is an alumina ceramic insulating spacer.

Further, the vibration sensing assembly comprises: a support 12, disposed on a side of the insulating spacer away from the first casing 1; a piezoelectric ceramic 11, disposed in a ring shape and sleeved on the columnar protrusion, and fixed by adhesive on the support 12; a mass block 10, having a groove structure that fits the piezoelectric ceramic 11; a signal processing circuit board 7, spaced apart from a side of the mass block 10 away from the insulating spacer, and connected to an inner wall of the shielding case 9 and a signal transmission line 16 extending from the shielding case 9; a columnar protrusion is disposed on one side of the support 12 away from the insulating spacer; and the piezoelectric ceramic 11 is disposed in the groove structure to form a structure of ring-shaped shear piezoelectric ceramic 11. The signal processing circuit board 7 is a PCB (printed circuit board). When the piezoelectric ceramic 11 is subjected to the shearing force of the mass block 10 due to the vibration, an electric charge is generated on the inner and outer surfaces of the piezoelectric ceramic 11 due to the piezoelectric effect, and then transmitted to the signal processing circuit board 7 through the signal transmission line 16 to realize a conversion from charge signal to the voltage signal.

Further, the shielding case 9 comprises a first layer structure for protecting the vibration sensing assembly and supporting the signal processing circuit board 7, and a second layer structure for shielding the first casing 1 from interfering with the signal processing circuit board 7. The shielding case 9 is provided with a through hole for leading out the signal transmission line 16 connected to the signal processing circuit board 7.

In this embodiment, the temperature sensor body is connected to the vibration sensor body and disposed perpendicular to the vibration sensor body, which is a probe structure.

Further, the temperature sensor body comprises a second casing 2 connected to the first casing 1, and a thermal resistor 15 disposed in the second casing 2. The thermal resistor 15 is two Pt100 platinum resistance elements. The resistance value of the resistance elements will increase as the temperature increases, and is realized a conversion from resistance value to temperature through an algorithm by an upper computer to realize a temperature signal acquisition. The thermal resistor 15 is connected to a signal transmission line 16 extending to an interior of the first casing 1. Further, the second casing 2 is internally filled with the pouring sealant 8, which is a thermal conductive adhesive. The design of the thermal conductive adhesive may reduce the temperature response time of the resistor, and play a role of fixation and insulation, which can effectively guarantee the sealing requirement and voltage resistance requirement of the temperature sensor body.

In this embodiment, the 12-core connector 3 is connected to the first casing 1.

In this embodiment, the connector 6 is connected to the 12-core connector 3 via a signal transmission cable 4. The signal transmission line 16 connected to the signal processing circuit board 7 and the signal transmission line 16 connected to the thermal resistor 15 are respectively connected to the 12-core connector 3. Further, both of the 12-core connector 3 and the connector 6 are connected to the signal transmission cables 4 by an adapter 5. The signal transmission cable 4 is externally equipped with a flame-retardant sleeve, which is clamped to the adapter 5 on both sides.

In this embodiment, a circuit, formed by a bidirectional transient voltage suppressing diode 14, a gas discharge tube 13, and a unidirectional diode, is disposed between the 12-core connector 3 and the signal processing circuit board 7, so that the signal processing circuit board may work normally under the action of an electrical fast pulse group.

In the present embodiment, the pouring sealant 8 is injected into the inner space of the first casing 1 and the second casing 2 through the probe holes for fixation and insulation. The pouring sealant 8 is filled into the interior of the first and second casings to ensure the voltage resistance requirements of the vibration sensor body and the temperature sensor body.

The electronic circuit in this embodiment is a lightning protection electronic circuit, so that the composite sensor has the functions of lightning protection and anti-electric fast pulse group, has superior environmental adaptability, and can adapt to the harsh environment inside the high-speed train power system.

When the vibration and temperature integrated sensor is mounted on the gearbox, the components such as the piezoelectric ceramic 11 may collect vibration information along with the vibration of the gearbox, and the temperature probe structure is used to sense the temperature information, so that the vibration and temperature of the gearbox can be detected at the same time. The vibration sensing assembly is insulated and isolated from the first casing 1 by the insulating spacer, the shielding case 9, and the pouring sealant 8 to meet the high voltage resistance requirement of the vibration sensing assembly. The insulating layer is designed to enhance the working stability and working life of the vibration sensing assembly. The alumina ceramic insulating spacer and the shielding case 9 are used to insulate the vibration sensing assembly from the first casing 1 and achieve electromagnetic shielding, so that the vibration sensing assembly has an excellent signal-to-noise ratio, which is good for capturing fine signals. The temperature signal collected by the Pt100 platinum resistor and the vibration signal processed by the signal processing circuit board 7 are connected to the signal transmission cable 4 through the signal line via the 12-core connector 3, and a terminal of the signal transmission cable 4 is connected to the signal processing device by using the connector 6, so as to complete the signal acquisition and transmission.

As an alternative embodiment, an insulating layer may also be formed only from a pouring sealant or from other insulating materials.

As an alternative embodiment, a vibration sensing assembly may also consist of a lateral vibration assembly and a vertical vibration assembly or of other form of vibration sensor assembly.

As an alternative embodiment, a temperature sensor body may also be a thermocouple type temperature sensor or other form of temperature sensor.

As an alternative embodiment, a shielding case may also be a one-layer structure.

It is apparent that the above embodiments are merely examples for clarity of illustration, and are not intended to limit the embodiments. Other variations or modifications of the various forms may be made by those skilled in the art in view of the above description. There is no need and no way to present all of the embodiments. The obvious variations or modifications derived therefrom are still within the scope of protection created by the present application.

What is claimed is:

1. A vibration and temperature integrated sensor, comprising
a vibration sensor body;
a temperature sensor body, coupled to the vibration sensor body;
wherein,
the vibration sensor body comprises a first casing and a vibration sensing assembly disposed inside the first casing; a shielding case is disposed outside the vibration sensing assembly; and the shielding case and the first casing have an insulating layer therebetween.

2. The vibration and temperature integrated sensor according to claim 1, wherein, the insulating layer comprises an insulating spacer, disposed at a bottom of the vibration sensing assembly, being in contact with the first casing, and connected to an opening of the shielding case to form a bearing chamber for bearing the vibration sensing assembly;
a pouring sealant, filled between the shielding case and the first outer casing.

3. The vibration and temperature integrated sensor according to claim 2, wherein the vibration sensing assembly comprises:
a support, disposed on a side of the insulating spacer away from the first casing;
a piezoelectric ceramic, disposed in a ring shape and sleeved on the columnar protrusion;
a mass block, having a groove structure that fits the piezoelectric ceramic;
a signal processing circuit board, spaced apart from a side of the mass block away from the insulating spacer, and connected to an inner wall of the shielding case and a signal transmission line extending from the shielding case;
a columnar protrusion is disposed on one side of the support away from the insulating spacer; and the piezoelectric ceramic is disposed in the groove structure.

4. The vibration and temperature integrated sensor according to claim 3, wherein, the shielding case comprises
a first layer structure for protecting the vibration sensing assembly and supporting the signal processing circuit board, and
a second layer structure for shielding the first casing from interfering with the signal processing circuit board.

5. The vibration and temperature integrated sensor according to claim 1, wherein the temperature sensor body is a probe structure.

6. The vibration and temperature integrated sensor according to claim 5, wherein the temperature sensor body comprises
a second casing connected to the first casing, and
is a thermal resistor, disposed in the second casing and connected to a signal transmission line extending to an interior of the first casing.

7. The vibration and temperature integrated sensor according to claim 6, wherein, the second casing is internally filled with the pouring sealant.

8. The vibration and temperature integrated sensor according to claim 6, further comprising
a 12-core connector connected to the first casing, and
a connector connected to the 12-core connector via a signal transmission cable;
wherein, the signal transmission line connected to the signal processing circuit board and the signal transmission line connected to the thermal resistor are respectively connected to the 12-core connector.

9. The vibration and temperature integrated sensor according to claim 8, wherein, both of the 12-core connector and the connector are connected to the signal transmission cables by an adapter.

10. The vibration and temperature integrated sensor according to claim 8, wherein, a circuit, formed by a bidirectional transient voltage suppressing diode, a gas discharge tube, and an unidirectional diode, is disposed between the 12-core connector and the signal processing circuit board.

11. The vibration and temperature integrated sensor according to claim 2, wherein the temperature sensor body is a probe structure.

12. The vibration and temperature integrated sensor according to claim 3, wherein the temperature sensor body is a probe structure.

13. The vibration and temperature integrated sensor according to claim 4, wherein the temperature sensor body is a probe structure.
